(19) United States
(12) Patent Application Publication
(10) Pub. No.: US 2021/0098548 A1
(43) Pub. Date: Apr. 1, 2021

(54) DISPLAY DEVICE

(71) Applicant: SHARP KABUSHIKI KAISHA, Sakai City, Osaka (JP)

(72) Inventors: HISAO OCHI, Sakai City, Osaka (JP); JUMPEI TAKAHASHI, Sakai City, Osaka (JP)

(21) Appl. No.: 17/041,140

(22) PCT Filed: Mar. 28, 2018
(86) PCT No.: PCT/JP2018/013000

§ 371 Date: Sep. 24, 2020

(51) Int. Cl. H01L 27/32; H01L 51/52

(52) U.S. Cl. CPC H01L 27/3258; H01L 27/3276; H01L 51/5253; H01L 51/5271

(57) ABSTRACT

A first metal layer on a resin substrate layer, a flattening film on the first metal layer, a second metal layer and a plurality of organic EL elements on the flattening film, and a sealing film covering the plurality of organic EL elements are provided. An organic layer provided in the sealing film includes a circumferential end edge positioned in a frame region in a periphery of a display region. A slit overlapping the circumferential end edge of the organic layer is formed in an outer side of the flattening film. The first metal layer and the second metal layer are in contact with each other inside the slit. A low reflection film is provided on a light reflective portion including the first and second metal layers at a location at which the organic layer and the slit overlap each other.

### TECHNICAL FIELD

The present disclosure relates to a display device.

### BACKGROUND ART

In recent years, an organic electroluminescence (EL) display device of the self-luminous type using an organic EL element has attracted attention as a display device that can replace a liquid crystal display device. The organic EL display device is provided with a sealing film that covers the organic EL element to suppress degradation of the organic EL element due to penetration of, for example, moisture and oxygen. As a sealing structure obtained by the sealing film, there has been proposed a structure in which a layered film including an organic layer and an inorganic layer constitutes the sealing film (for example, see PTL 1). The organic layer constituting the sealing film is formed by an ink-jet method, for example.

### CITATION LIST

### Patent Literature

PTL 1: JP 2011-175300 A

### SUMMARY OF INVENTION

### Technical Problem

Incidentally, the film formation properties of an organic layer formed by an ink-jet method are easily affected by a state of a film formed surface, and thus it is difficult to form a peripheral edge (edge) of the organic layer at high accuracy. When the organic layer is formed, a material (ink) of the organic layer is not applied to a predetermined position in a frame region, and stagnates on a display region side such as a part in which a monolithic circuit is present. In this case, when a foreign matter is present at a location that is originally intended to be covered with the organic layer, a sealing film fails to cover the foreign matter, and a defect may be caused in the sealing film.

For this reason, it is necessary to confirm that the material forming the organic layer is applied to the predetermined position in the frame region at a step of forming the sealing film. However, in the part of the frame region including the peripheral edge position of the organic layer, a metal layer constituting an electrode of the organic EL element and a frame wiring line is formed, and a metal material such as silver (Ag) having high reflectivity is suitably used for the metal layer Thus, due to light reflected by the metal layer, it is difficult to confirm a coating position of the material forming the organic layer.

A technique of the present disclosure has been made in view of this point, and an object of the present disclosure is to securely confirm that a material forming an organic layer is applied to a predetermined position in a frame region.

### Solution to Problem

A display device according to the technique of the present disclosure includes a substrate, a first metal layer being provided on the substrate, a flattening film being provided on the first metal layer, a second metal layer and a plurality of light-emitting elements being provided on the flattening film, and a sealing film covering the plurality of light-emitting elements, wherein a display region and a frame region are provided, the display region in which an image is displayed by light emission of the plurality of light-emitting elements, and the frame region being positioned in a periphery of the display region, the sealing film includes an organic layer, and the organic layer includes a circumferential end edge being positioned in the frame region, a slit is formed in an outer side of the flattening film, the slit overlapping the circumferential end edge of the organic layer, the first metal layer and the second metal layer are each provided across the slit, and are in contact with each other inside the slit, and a low reflection film is provided on the second metal layer at a location at which the organic layer and the slit overlap each other, the low reflection film having light reflectivity lower than light reflectivity of the second metal layer.

### Advantageous Effects of Invention

According to the display device described above, the low reflection film is provided on the second metal layer that is in contact with the first metal layer inside the slit of the flattening film in the frame region at a location at which the organic layer and the slit overlap each other. Thus, at a location at which the low reflection film is provided, light reflection is reduced. Even when a metal material having high reflectivity is used for the second metal layer, it is possible to securely confirm that the material for forming the organic layer is applied to the predetermined position in the frame region in manufacturing of the display device. Accordingly, inspection for a coating region of the organic layer can be performed easily, and the number of defective panels fed to the next step can be reduced.

### BRIEF DESCRIPTION OF DRAWINGS

FIG. 1 is a plan view illustrating a schematic configuration of an organic EL display device according to an embodiment.

FIG. 2 is a plan view illustrating a part of a display region surrounded by II of the organic EL display device of FIG. 1.

FIG. 3 is an equivalent circuit diagram of a part of a TFT layer constituting the organic EL display device according to the embodiment.

FIG. 4 is a cross-sectional view at a location taken along line IV-IV of the display region of FIG. 2.

FIG. 5 is a cross-sectional view illustrating a structure of an organic EL layer constituting the organic EL display device.

FIG. 6 is a plan view illustrating a part surrounded by VI of the organic EL display device of FIG. 1.

FIG. 7 is a cross-sectional view at a location taken along line VII-VII of the organic EL display device of FIG. 6.

FIG. 8 is a view equivalent to FIG. 6 of an organic EL display device according to a first modification example of the embodiment.

FIG. 9 is a view equivalent to FIG. 6 of an organic EL display device according to a second modification example of the embodiment.

FIG. 10 is a view equivalent to FIG. 6 of an organic EL display device according to a third modification example of the embodiment.

FIG. 11 is a view equivalent to FIG. 7 of an organic EL display device according to a fourth modification example of the embodiment.

FIG. 12 is a view equivalent to FIG. 7 of an organic EL display device according to a fifth modification example of the embodiment.

### DESCRIPTION OF EMBODIMENTS

With reference to the drawings, exemplary embodiments will be described below in detail.

In the present embodiment, an organic EL display device is described as an example with regard to a display device according to the technique of the present disclosure.

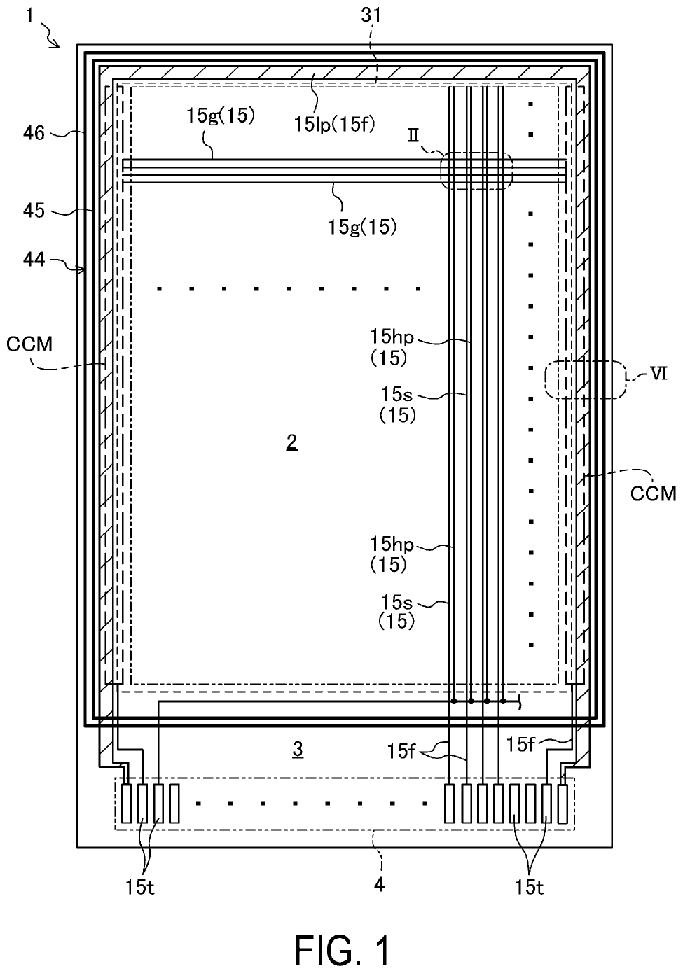

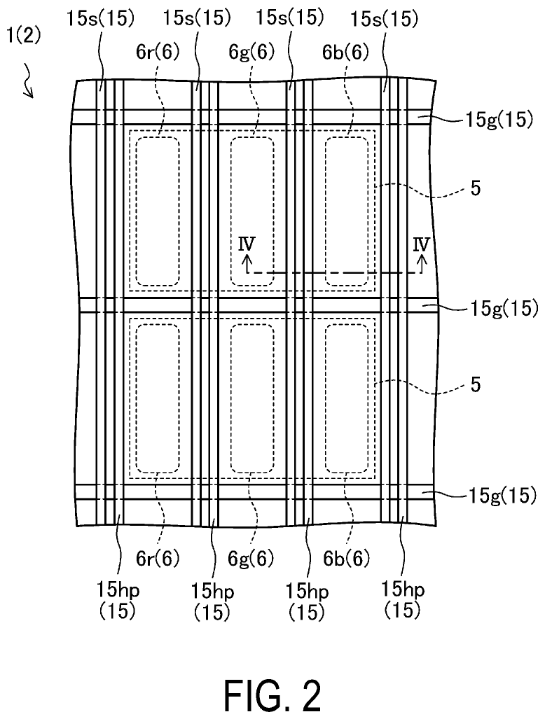

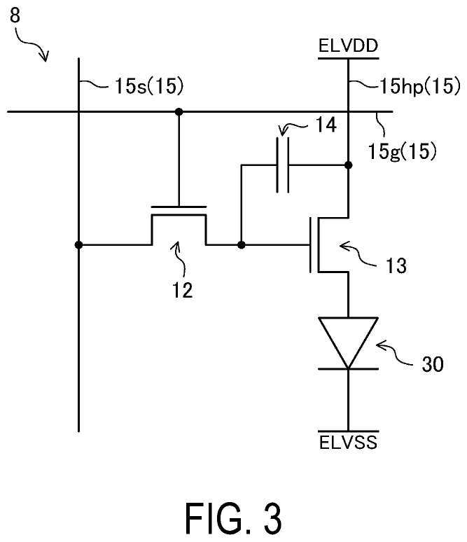

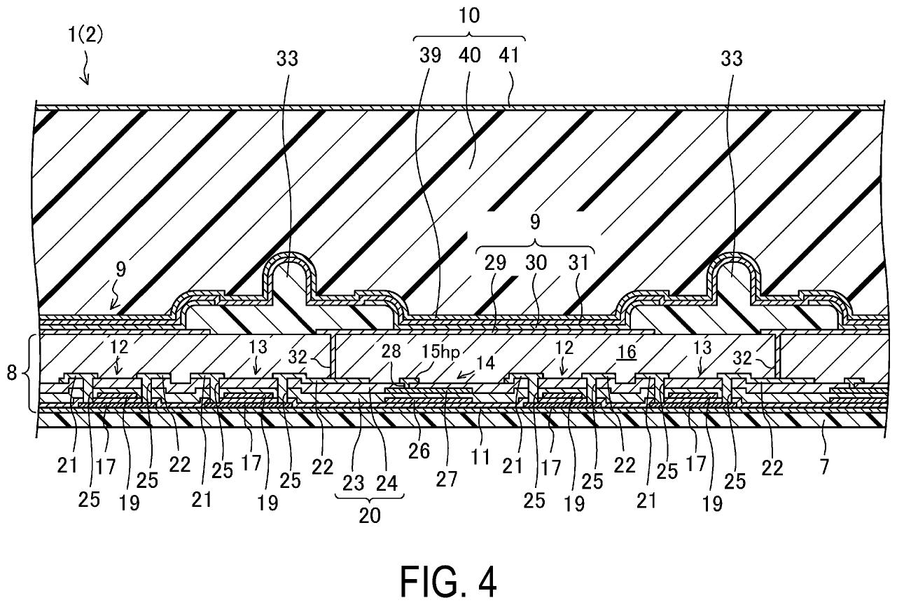

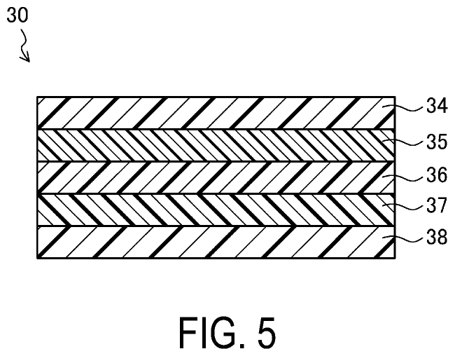

FIG. 1 is a plan view illustrating a schematic configuration of an organic EL display device 1. FIG. 2 is a plan view illustrating a part of a display region 2 surrounded by II of the organic EL display device 1 of FIG. 1. FIG. 3 is an equivalent circuit diagram of a part of a TFT layer 8 constituting the organic EL display device 1. FIG. 4 is a cross-sectional view at a location taken along line IV-IV of the display region 2 of FIG. 2. FIG. 5 is a cross-sectional view illustrating a structure of an organic EL layer 30 constituting the organic EL display device 1.

As illustrated in FIG. 1, the organic EL display device 1 includes the display region 2 having a rectangular shape in which an image is displayed and a frame region 3 having a rectangular shape and provided in a periphery of the display region 2. Then, a terminal portion 4 to be coupled to an external circuit is provided in a part constituting one side of the frame region 3. Although not illustrated, one end portion of a circuit board such as a flexible printed circuit (FPC) is coupled to the terminal portion 4.

Further, a part of the frame region 3 constitutes each of the sides adjacent to the side provided with the terminal portion 4 (each of the right side and the left side of FIG. 1). The part includes a control circuit region CCM in which a control circuit such as a gate driver circuit (not illustrated) is formed monolithically on a substrate (a resin substrate layer 7 described below). Additionally, between the display region 2 and the terminal portion 4 in the frame region 3, a plurality of frame wiring lines 15f are provided. Each of the frame wiring lines 15f constitutes a wiring line terminal 15t electrically coupled to a circuit board in the terminal portion 4. In the terminal portion 4, a plurality of the wiring line terminals 15t are aligned in a predetermined pattern.

The plurality of frame wiring lines 15f include a low voltage power source wiring line 15lp (indicated with a hatched area) that is electrically coupled to a second electrode 31 of an organic EL element 9 described below. The low voltage power source wiring line 15lp is provided to surround the display region 2 in the parts constituting the three sides of the frame region 3 except for the side provided with the terminal portion 4, and is drawn out to the terminal portion 4, The low voltage power source wiring line 15lp is electrically coupled to a low voltage power source (ELVSS), which is not illustrated, via the terminals 15t provided in the terminal portion 4.

The organic EL display device 1 employs an active matrix driving method. In the display region 2, a plurality of pixels 5 illustrated in FIG. 2 are disposed in a matrix shape. For example, each of the pixels 5 includes three color subpixels 6 being a subpixel Or for displaying a red color, a subpixel 6g for displaying a green color, and a subpixel 6b for displaying a blue color. Those subpixels 6r, 6g, and 6b of the three colors are aligned with a juxtaposition, and are adjacent to one another in a stripe shape.

As illustrated in FIG. 4, the organic EL display device 1 includes the resin substrate layer 7 being a substrate, a thin film transistor (TFT) layer 8 provided on the resin substrate layer 7, a plurality of the organic EL elements 9 being light-emitting elements provided on the TFT layer 8, and a sealing film 10 that covers the plurality of organic EL elements 9.

The resin substrate layer 7 is formed of, for example, a polyimide resin, and has flexibility.

The TFT layer 8 includes a base coat film 11 provided on the resin substrate layer 7, a plurality of first TFTs 12, a plurality of second TFTs 13, a plurality of capacitors 14, and various display wiring lines 15, which are provided on the base coat film 11, and a flattening film 16 that covers the first TFTs 12, the second TFTs 13, the capacitors 14, and the display wiring lines 15.

The base coat film 11 includes a single-layer film or a layered film of an inorganic insulating layer of, for example, silicon nitride, silicon oxide, silicon oxide nitride, or the like. Each of the first TFTs 12, each of the second TFTs 13, and each of the capacitors 14 are provided for each of the subpixels 6.

As illustrated in FIG. 2 and FIG. 3, as the display wiring lines 15, a plurality of gate wiring lines 15g extending in parallel with each other, a plurality of source wiring lines 15s extending in parallel with each other in a direction intersecting the gate wiring lines 15g, and a plurality of high voltage power source wiring lines 15hp extending along the source wiring lines 15s are provided. Additionally, the gate wiring lines 15g, the source wiring lines 15s, and the high voltage power source wiring lines 15hp are insulated from one another, and are formed in a lattice pattern as a whole to define the subpixels 6.

Each of the source wiring lines 15s and each of the high voltage wiring lines 15hp are drawn out from the display region 2 to the terminal portion 4 as the frame wiring lines 15f. Each of the high voltage wiring lines 15hp is electrically coupled to a high voltage power source (ELVDD), which is not illustrated, via the terminals 15t provided in the terminal portion 4. Each of the gate wiring lines 15g is coupled to the gate driver circuit in the control circuit region CCM, and is sequentially driven by the gate driver circuit.

The first TFT 12 and the second TFT 13 are examples of an active element, and employ a top gate type structure, for example. Specifically, the first TFT 12 and the second TFT 13 each include a semiconductor layer 17 provided in an island shape on the base coat film 11, a gate insulating film 18 that covers the semiconductor layer 17, a gate electrode 19 that overlaps a part (channel region) of the semiconductor layer 17 via the gate insulating film 18, an interlayer insulating film 20 that covers the gate electrode 19, and a source electrode 21 and a drain electrode 22 that are provided on the interlayer insulating film 20.

The gate electrode 19 is formed of a material identical to a material of the plurality of gate wiring lines 15g in a layer identical to a layer of the plurality of gate wiring lines 15g. The interlayer insulating film 20 includes a layered film including a first interlayer insulating film 23 and a second interlayer insulating film 24. The first interlayer insulating film 23, the second interlayer insulating film 24, and the gate insulating film 18 each include a single-layer film or a layered film of an inorganic insulating layer of, for example, silicon nitride, silicon oxide, silicon oxide nitride, or the like.

The source electrode 21 and the drain electrode 22 are separated from each other, and are respectively coupled to different parts (the source region and the drain region) of the semiconductor layer 17 via contact holes 25 formed in the gate insulating film 18 and the interlayer insulating film 20. In the display region 2, the source electrode 21 and the drain electrode 22 are formed of a material identical to a material of the plurality of source wiring lines 15s in a layer identical to a layer of the plurality of source wiring lines 15s. The source electrode 21 is formed of aluminum (Al), for example.

In the first TFT 12, the gate electrode 19 is provided in an integrated manner with the corresponding gate wiring line 15g, the source electrode 21 is provided in an integrated manner with the corresponding source wiring line 15s, and the drain electrode 22 is electrically coupled to the gate electrode 19 and the capacitor 14 of the second TFT 13. In the second TFT 13, the source electrode 21 is electrically coupled to the high voltage power source wiring line 15hp.

The capacitor 14 is coupled to the corresponding first TFT 12 and the corresponding high voltage power source wiring line 15hp. The capacitor 14 includes a lower conductive layer 26 provided on the gate insulating film 18, the first interlayer insulating film 23 that covers the lower conductive layer 26, and an upper conductive layer 27 that overlaps the lower conductive layer 26 via the first interlayer insulating film 23. The lower conductive layer 26 is formed of a material identical to a material of the gate electrode 19 in a layer identical to a layer of the gate electrode 19. The upper conductive layer 27 is coupled to the high voltage power source wiring line 15hp via a contact hole 28 formed in the second interlayer insulating film 24.

In the display region 2, the flattening film 16 covers parts except for a part of the drain electrode 22 of the second TFT 13. Accordingly, a surface of the TFT layer 8 is flattened not to reflect the source wiring line 15s, the high voltage power source wiring line 15hp, and surface shapes of the first TFT 12 and the second TFT 13. The flattening film 16 is formed of a colorless transparent organic resin material such as an acrylic resin.

The organic EL element 9 is provided in each of the subpixels 6 on the flattening film 16, The display region 2 includes the organic EL element 9. The organic EL element 9 employs a top-emitting type structure. Specifically, the organic EL element 9 includes a first electrode 29 provided in a surface of the flattening film 16, the organic EL layer 30 being a function layer provided on the first electrode 29, and the second electrode 31 overlapping the first electrode 29 via the organic EL layer 30.

A plurality of the first electrodes 29 are disposed in a matrix shape. Each of the first electrodes 29 is provided for each of the organic EL elements 9, and is coupled to the drain electrode 22 of the second TFT 13 in the corresponding subpixel 6 via a contact hole 32 formed in the flattening film 16. The first electrode 29 has a function to inject a positive hole (hole) into the organic EL layer 30, and is preferably formed of a material having a large work function to improve hole injection efficiency into the organic EL layer 30.

Examples of a material of the first electrode 29 include a metal material such as silver (Ag), aluminum (Al), vanadium (V), cobalt (Co), nickel (Ni), tungsten (W), gold (Au), calcium (Ca), titanium (Ti), yttrium (V), sodium (Na), ruthenium (Ru), manganese (Mn), indium (In), magnesium (Mg), lithium (Li), ytterbium (Yb), and lithium fluoride (LiF).

Additionally, for example, the material of the first electrode 29 may be an alloy such as magnesium (Mg)-copper (Cu), magnesium (Mg)-silver (Ag), sodium (Na)-potassium (K), astatine (At)-astatine oxide (AtO₂), lithium (Li)-aluminum (Al), lithium (Li)-calcium (Ca)-aluminum (Al), and lithium fluoride (LiF)-calcium (Ca)-aluminum (Al).

Additionally, for example, the material of the first electrode 29 may be a conductive oxide such as tin oxide (SnO), zinc oxide (ZnO), indium tin oxide (ITO), and indium zinc oxide (IZO). Additionally, the first electrode 29 may be formed by layering a plurality of layers including the materials described above. Note that examples of the material having a large work function include indium tin oxide (ITO) and indium zinc oxide (IZO). In the present embodiment, the first electrode 29 is formed of silver (Ag).

The first electrodes 29 of the adjacent subpixels 6 are defined by an edge cover 33. The edge cover 33 is formed in a lattice pattern, and covers a peripheral portion of each of the first electrodes 29. Examples of a material of the edge cover 33 include an inorganic compound such as silicon oxide, silicon nitride, and silicon oxynitride, and an organic resin material such as a polyimide resin, an acrylic resin, a polysiloxane resin, and a novolac resin.

The organic EL layer 30 is provided for each of the organic EL elements 9. The organic EL layer 30 includes a structure in which a hole injection layer 34, a hole transport layer 35, a light-emitting layer 36, an electron transport layer 37, and an electron injection layer 38 illustrated in FIG. 5 are layered in this order on the first electrode 29,

The hole injection layer 34 is also referred to as an anode electrode buffer layer, and has a function to improve efficiency of hole injection from the first electrode 29 into the organic EL layer 30 by bringing energy levels of the first electrode 29 and the organic EL layer 30 closer to each other. Examples of a material of the hole injection layer 34 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 35 has a function to improve efficiency of hole transport from the first electrode 29 to the organic EL layer 30. Examples of a material of the hole transport layer 35 include a porphyrin derivative, an aromatic tertiary amine compound, a styrylamine derivative, polyvinylcarbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted alcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, and zinc selenide.

The light-emitting layer 36 has a function to recombine a hole injected from the first electrode 29 and an electron injected from the second electrode 31 and emit light when a voltage is applied by the first electrode 29 and the second electrode 31. The light-emitting layer 36 is formed of a material that varies in accordance with a luminescent color (for example, red, green, or blue) of the organic EL element 9 in the individual subpixel 6.

Examples of a material of the light-emitting layer 36 include a metal oxinoid compound (8-hydroxyquinoline metal complex), a naphthalene derivative, an anthracene derivative, a diphenyl ethylene derivative, a vinyl acetone derivative, a triphenylamine derivative, a butadiene derivative, a coumarin derivative, a benzoxazole derivative, an oxadiazole derivative, a benzothiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rhodamine derivative, an aquidine derivative, phenoxazone, a quinacridone derivative, rubrene, poly-p-phenylenevinylene, and polysilane.

The electron transport layer 37 has a function to facilitate migration of an electron to the light-emitting layer 36 efficiently. Examples of a material of the electron transport layer 37 include an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound, as an organic compound.

The electron injection layer 38 is also referred to as a cathode electrode buffer layer, and has a function to improve electron injection efficiency from the second electrode 31 into the organic EL layer 30 by bringing energy levels of the second electrode 31 and the organic EL layer 30 closer to each other. Examples of a material of the electron injection layer 38 include an inorganic alkaline compound such as lithium fluoride (LiF), magnesium fluoride (Nigh), calcium fluoride (CaF₂), strontium fluoride (SrF₂), and barium fluoride (BaF₂), aluminum oxide (Al₂O₃), and strontium oxide (SrO).

As illustrated in FIG. 4, the second electrode 31 is provided in and shared by the plurality of organic EL elements 9 (that is, shared by the plurality of subpixels 6), and covers the organic EL layer 30. The second electrode 31 is coupled to the low voltage power source wiring line 15lp, and conduction with a low voltage power source (ELVSS) is established at the wiring line terminal 15t provided in the terminal portion 4 through the low voltage power source wiring line 15lp. The second electrode 31 has a function to inject an electron into the organic EL layer 30, and is preferably formed of a material having a small work function to improve electron injection efficiency into the organic EL layer 30.

Examples of a material of the second electrode 31 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF),

Additionally, examples of a material of the second electrode 31 include an alloy of magnesium (Mg)-copper (Cu), an alloy of magnesium (Mg)-silver (Ag), an alloy of sodium (Na)-potassium (K), an alloy of astatine (At)-astatine oxide (AtO₂), an alloy of lithium (Li)-aluminum (Al), an alloy of lithium (Li)-calcium (Ca)-aluminum (Al), and an alloy of lithium fluoride (LiF)-calcium (Ca)-aluminum (Al).

Additionally, for example, the material of the second electrode 31 may be a conductive oxide such as tin oxide (SnO), zinc oxide (ZnO), indium tin oxide (ITO), and indium zinc oxide (IZO). Additionally, the second electrode 31 may be formed by layering a plurality of layers including the materials described above. Note that examples of the material having a small work function include magnesium (Mg), lithium (Li), lithium fluoride (LiF), an alloy of magnesium (Mg)-copper (Cu), an alloy of magnesium (Mg)-silver (Ag), an alloy of sodium (Na)-copper (Cu), an alloy of magnesium (Mg)-silver (Ag), an alloy of sodium (Na)-potassium (K), an alloy of lithium (Li)-aluminum (Al), an alloy of lithium (Li)-calcium (Ca)-aluminum (Al), and an alloy of lithium fluoride (LiF)-calcium (Ca)-aluminum (Al).

The sealing film 10 has a function to protect the organic EL element 9 from moisture, oxygen, and the like. As illustrated in FIG. 4, the sealing film 10 includes a first inorganic layer 39 covering the second electrode 31, an organic layer 40 provided on the first inorganic layer 39, and a second inorganic layer 41 covering organic layer 40.

The first inorganic layer 39 and the second inorganic layer 41 are formed of, for example, an inorganic material such as silicon oxide (SIO₂), aluminum oxide (Al₂O₃), and silicon carbonitride (Si₃N₄). The organic layer 40 is formed of, for example, an organic resin material such as an acrylate, an epoxy resin, a silicone resin, polyurea, parylene, polyimide, and polyamide.

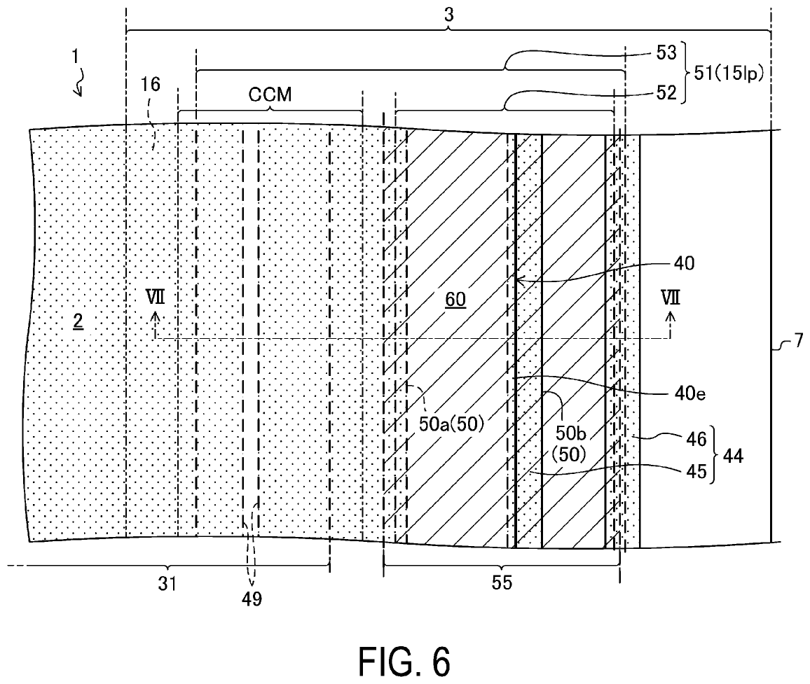

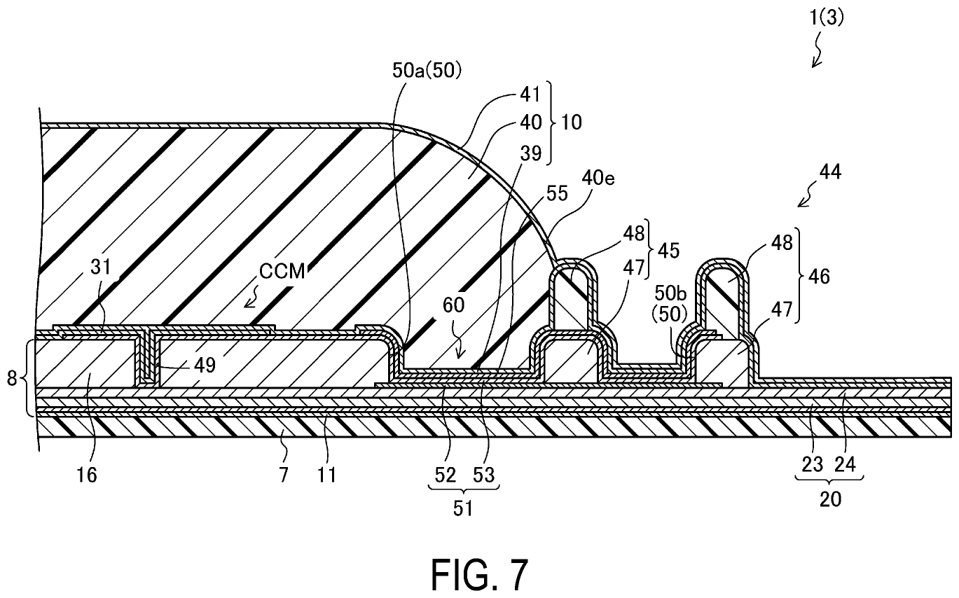

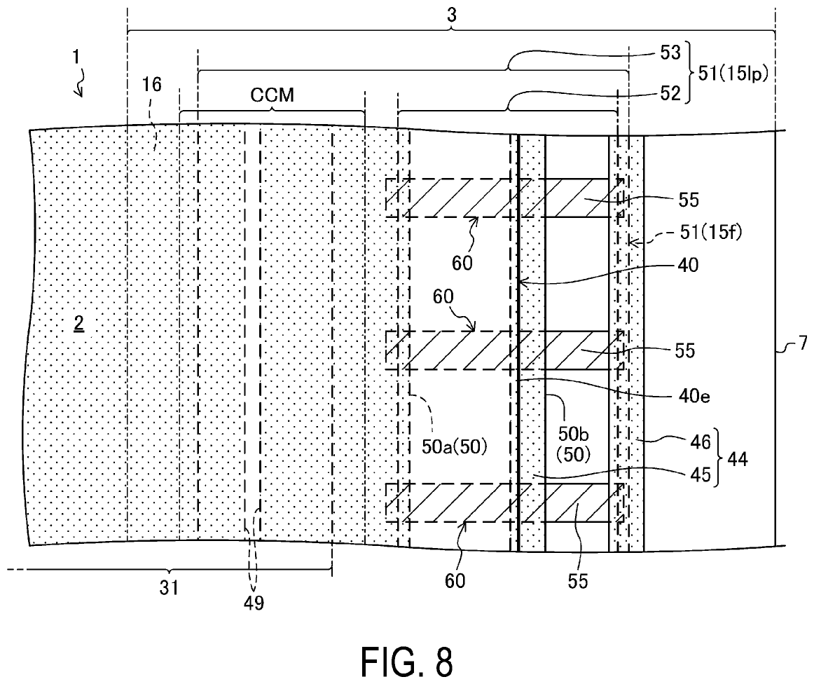

FIG. 6 is a plan view illustrating a part surrounded by VI of the organic EL display device 1 of FIG. 1. Additionally, FIG. 7 is a cross-sectional view at a location taken along line VII-VII of the organic EL display device 1 of FIG. 6. Note that, in FIG. 6, a region in which the flattening film 16, a first dam wall 45, and a second dam wall 46 are formed is indicated by dots, and a region in which a low reflection film 55 is formed is indicated by a line extending diagonally upward to the right. Additionally, the first inorganic layer 39 and the second inorganic layer 41 constituting the sealing film 10 are omitted in the figure, and a circumferential end edge 40e of the organic layer 40 is indicated by a bold line. The same applies to FIG. 8 to FIG. 10 referred in modification examples described below.

The first inorganic layer 39, the organic layer 40, and the second inorganic layer 41 are provided in all the display region 2, and are also provided in the frame region 3 as illustrated in FIG. 6 and FIG. 7. A circumferential end edge of each of the first inorganic layer 39, the organic layer 40, and the second inorganic layer 41 is positioned in the frame region 3. In the frame region 3, the circumferential end edge 40e of the organic layer 40 is positioned on the display region 2 side with respect to the circumferential end edges of the first inorganic layer 39 and the second inorganic layer 41.

The frame region 3 is provided with a dam structure 44 for damming back a spread of an organic resin material that is formed into the organic layer 40 in a process of manufacturing the organic EL display device 1. The dam structure 44 includes the first dam wall 45 surrounding the display region 2 and the second dam wall 46 surrounding the first dam wall 45.

The first dam wall 45 and the second dam wall 46 are formed in rectangular shapes similar to each other (see FIG. 1), and are disposed at an interval in the width direction of the frame region 3. The first dam wall 45 and the second dam wall 46 each include a structure in which a first wall layer 47 and a second wall layer 48 are layered. The first wall layer 47 is formed of a material identical to a material of the flattening film 16 in a layer identical to a layer of the flattening film 16. The second wall layer 48 is formed of a material identical to a material of the edge cover 33 in a layer identical to a layer of the edge cover 33.

In the flattening film 16, a trench 49 passing through the flattening film 16 is formed. The trench 49 extends along each side of the frame region 3, divides the flattening film 16, and has a function to prevent moisture from entering the display region 2. Additionally, in an outer side of the flattening film 16, a slit 50 that exposes a lower layer of the flattening film 16 is formed in one side of the flattening film 16. Specifically, between the flattening film 16 and the first dam wall 45, a first slit 50a is formed as the slit 50. Additionally, between the first dam wall 45 and the second dam wall 46, a second slit 50b is formed as the slit 50.

The organic layer 40 is provided from the display region 2 to at least the first dam wall 45, and is in contact with the first dam wall 45. Then, the circumferential end edge 40e of the organic layer 40 overlaps the first slit 50a. In the examples illustrated in FIG. 6 to FIG. 8, the organic layer 40 is provided fully in an inner side of the first dam wall 45, but is dammed back by the first dam wall 45 and is not provided in an outer side of the first dam wall 45. The organic layer 40 described above covers various elements and circuits such as the organic EL elements 9 and the gate driver circuit. When foreign matters are present at formation locations of the various elements and circuits, the organic layer 40 has a function as a buffer layer that covers and completely envelops the foreign matters and that prevents a defect from being caused in the sealing film 10.

The first inorganic layer 39 and the second inorganic layer 41 cover both the first dam wall 45 and the second dam wall 46. Circumferential end edge portions of the first inorganic layer 39 and the second inorganic layer 41 are joined to each other in the outer side of the first dam wall 45. That is, the organic layer 40 is enveloped by the first inorganic layer 39 and the second inorganic layer 41, and is encapsulated between the first inorganic layer 39 and the second inorganic layer 41.

In the frame region 3, a light reflective portion 51 that reflects incident light from the surface side is provided in a lower layer with respect to the sealing film 10. The light reflective portion 51 includes a first metal layer 52 provided in a lower layer of the flattening film 16 and a second metal layer 53 provided in an upper layer of the flattening film 16. The first metal layer 52 and the second metal layer 53 constitute the low voltage power source wiring line 15lp to surround the display region 2.

The first metal layer 52 is formed of a material (Al) identical to a material (Al) of the source wiring line 15s, the source electrode 21 and the drain electrode 22 in the display region 2 in a layer identical to a layer of the source wiring line 15s, the source electrode 21, and the drain electrode 22, and is provided on the interlayer insulating film 20. As illustrated in FIG. 7, in the frame region 3, the first metal layer 52 is provided from a region overlapping the flattening film 16 to the second dam wall 46, and is exposed inside the first slit 50a and inside the second slit 50b from the flattening film 16, the first dam wall 45, and the second dam wall 46.

The second metal layer 53 is formed of a material (Ag) identical to a material (Ag) of the first electrode 29 of the organic EL element 9 in a layer identical to a layer of the first electrode 29, and is provided on the flattening film 16. The second metal layer 53 is provided on the flattening film 16 to the second dam wall 46, and is positioned between the first wall layer 47 and the second wall layer 48 that constitute each of the first dam wall 45 and the second dam wall 46. Then, the second metal layer 53 overlap the first metal layer 52 to be in contact with the first metal layer 52 inside the first slit 50a and inside the second slit 50b, and is electrically coupled to the first metal layer 52.

Additionally, on the flattening film 16, the second metal layer 53 is provided from the outer side of the flattening film 16 with respect to the trench 49 to the display region 2 side with respect to the trench 49, and covers an inner face of the trench 49. On the flattening film 16, the second electrode 31 is provided from the display region 2 side with respect to the trench 49 to the outer peripheral side of the flattening film 16 with respect to the trench 49, and overlaps the second metal layer 53 to be in contact with the second metal layer 53, and covers the inner face of the trench 49 together with the second metal layer 53.

In this manner, the inner face of the trench 49 is covered with the second metal layer 53 and the second electrode 31. Accordingly, moisture from an external environment can be prevented from entering the display region 2 in the organic EL display device 1 through the trench 49. The second metal layer 53 and the second electrode 31 overlap each other to be in contact with each other on the flattening film 16 and inside the trench 49, and are electrically coupled to each other. Then, the second electrode 31 is electrically coupled to the first metal layer 52 via the second metal layer 53.

As described above, the first metal layer 52 and the second metal layer 53 are provided across the first slit 50a and the second slit 50b, and are in contact with each other inside the first slit 50a and inside the second slit 50b. The light reflective portion 51 including the first metal layer 52 and the second metal layer 53 satisfies a positional relationship of overlapping the circumferential end edge portion of the organic layer 40 over the first inorganic layer 39 inside the first slit 50a,

On the light reflective portion 51 (that is, on the second metal layer 53), the low reflection film 55 having light reflectivity lower than light reflectivity of the second metal layer 53 is provided. The low reflection film 55 is formed of a metal material. As the metal material, molybdenum (Mo) is used, for example. The film thickness of the low reflection film 55 is 100 nm or more and 300 nm or less, for example. As with the first metal layer 52 and the second metal layer 53, the low reflection film 55 is provided across the first slit 50a and the second slit 50b, from the flattening film 16 on the display region 2 side with respect to the first dam wall 45 through a part between the first dam wall 45 and the second dam wall 46, further to the second dam wall 46.

The low reflection film 55 is layered on the second metal layer 53, and is positioned between the first wall layer 47 and the second wall layer 48 that constitute each of the first dam wall 45 and the second dam wall 46. The low reflection film 55 is provided in a solid-like state between the flattening film 16 and the second dam wall 46. That is, the low reflection film 55 is provided in a solid-like state between the flattening film 16 and the first dam wall 45, and between the first dam wall 45 and the second dam wall 46. Then, the low reflection film 55 covers the light reflective portion 51 (second metal layer 53) inside the first slit 50a and inside the second slit 50b.

A location at which the low reflection film 55 is provided in the organic EL display device 1 is an inspected portion 60 for confirming a coating position of the material forming the organic layer 40. In the inspected portion 60, the first metal layer 52, the second metal layer 53, and the low reflection film 55 are layered in order on the interlayer insulating film 20, and the light reflective portion 51 is covered with the low reflection film 55. In the inspected portion 60 describe above, light reflection is reduced due to the low reflection film, and it is possible to confirm whether the organic layer 40 is formed to the position corresponding to the low reflection film 55, that is, to confirm a position of the circumferential end edge of the organic layer 40.

In the organic EL display device 1 including the above-described configuration, in each of the subpixels 6, a gate signal is input to the first TFT 12 via the gate wiring line 15g to turn on the first TFT 12, a predetermined voltage corresponding to a source signal is written in the gate electrode 19 and the capacitor 14 of the second TFT 13 via the source wiring line 15s, and a current corresponding to a gate voltage of the second TFT 13 is supplied from the high voltage power source wiring line 15hp to the organic EL element 9. Accordingly, the light-emitting layer 36 of the organic EL layer 30 emits light, and an image is displayed. Note that, in the organic EL display device 1, even when the first TFT 12 is turned off, the gate voltage of the second TFT 13 is held by the capacitor 14, and thus, light emission performed by the organic EL layer 30 (the light-emitting layer 36) is maintained for each of the subpixels 6 until a gate signal of the next frame is input.

The organic EL display device 1 described above can be manufactured by, for example, forming the TFT layer 8, and the organic EL element 9 with use of a known method on the resin substrate layer 7 formed on a surface of a glass substrate, then forming the low reflection film 55, subsequently forming the sealing film 10 with use of a known method, and further peeling the glass substrate from the resin substrate layer 7,

In manufacturing of the organic EL display device 1 described above, at a step of forming the low reflection film 55, a metal film including molybdenum (Mo) or the like is formed by sputtering or vapor deposition on the substrate on which the second electrode 31 of the organic EL element 9 and the second metal layer 53 are formed, and subsequently, the metal film is subjected to patterning by subjecting the metal film to photolithography treatment (resist application, prebaking, light exposure, developing, postbaking, etching, and resist peel), and thus, the low reflection film 55 is formed.

Additionally, at a step of forming the sealing film 10, the organic layer 40 is formed by an ink-jet method. In this case, to confirm that the material forming the organic layer 40 is applied to a predetermined position in the frame region 3, that is, to at least the first dam wall 45, the inspected portion 60 is subjected to inspection for confirming a coating position of the material forming the organic layer 40.

According to the organic EL display device 1 according to the present embodiment, on the light reflective portion 51 including the first metal layer 52 and the second metal layer 53 that are in contact with each other inside the first slit 50a and inside the second slit 50b of the flattening film 16 in the frame region 3, the low reflection film 55 is provided at a location at which the organic layer 40 and the first slit 50a overlap each other. Thus, at the location at which the low reflection film 55 is provided, light reflection is reduced, Even when a metal material having high reflectivity is used for the second metal layer 53 of the upper layer of the light reflective portion 51, it is possible to securely confirm that the material for forming the organic layer 40 is applied to the predetermined position in the frame region 3 in manufacturing of the display device 1. Accordingly, inspection for a coating region of the organic layer 40 can be performed easily, and the number of defective panels fed to the next step can be reduced.

### First Modification Example of Embodiment

FIG. 8 is a view equivalent to FIG. 6 of an organic EL display device 1 according to a first modification example of the embodiment. In the organic EL display device 1 according to the embodiment described above, the low reflection film 55 is provided in a solid-like state between the flattening film 16 and the second dam wall 46. However, as illustrated in FIG. 8, in the organic EL display device 1 according to the first modification example of the embodiment, a low reflection film 55 is provided in an island shape between a flattening film 16 and a second dam wall 46, and a plurality of the low reflection films 55 are aligned at an interval along a first dam wall 45.

Each of the low reflection films 55 is formed in, for example, a narrow rectangular shape, and is provided from the flattening film 16 to the second dam wall 46. That is, between the flattening film 16 and the first dam wall 45 and between the first dam wall 45 and the second dam wall 46, the low reflection film 55 is provided in an island shape. Then, the location at which the low reflection film 55 is provided constitutes an inspected portion 60 for confirming a coating position of a material forming an organic layer 40. Similarly, according to this configuration, effects similar to the effects in the above-described embodiment can be obtained.

### Second Modification Example of Embodiment

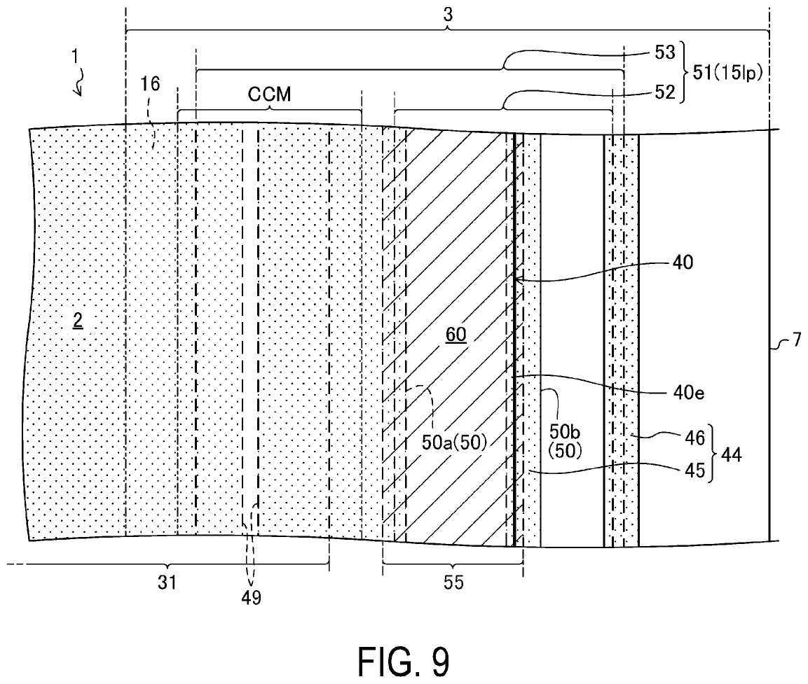

FIG. 9 is a view equivalent to FIG. 6 of an organic EL display device 1 according to a second modification example of the embodiment. In the organic EL display device 1 according to the embodiment described above, the low reflection film 55 is provided from the flattening film 16 to the second dam wall 46. However, as illustrated in FIG. 9, in the organic EL display device 1 according to the second modification example of the embodiment, a low reflection film 55 is provided in a solid-like state from a flattening film 16 to a first dam wall 45. That is, the low reflection film 55 is provided between the flattening film 16 and the first dam wall 45, but is not provided between the first dam wall 45 and a second dam wall 46. Then, the location at which the low reflection film 55 is provided constitutes an inspected portion 60 for confirming a coating position of a material forming an organic layer 40. Similarly, according to this configuration, effects similar to the effects in the above-described embodiment can be obtained.

### Third Modification Example of Embodiment

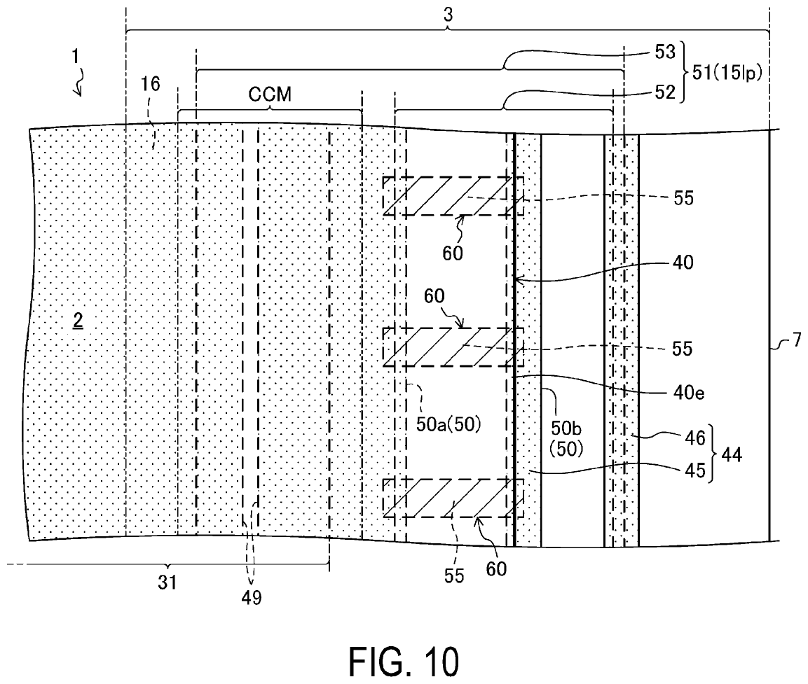

FIG. 10 is a view equivalent to FIG. 6 of an organic EL display device 1 according to a third modification example of the embodiment. In the organic EL display device 1 according to the second modification example described above, the low reflection film 55 is provided in a solid-like state from the flattening film 16 to the first dam wall 45. However, as illustrated in FIG. 10, in the organic EL display device 1 according to the third modification example of the embodiment, a low reflection film 55 is provided in an island shape between a flattening film 16 and a first dam wall 45, and a plurality of the low reflection films 55 are aligned at an interval along the first dam wall 45. Then, the location at which the low reflection film 55 is provided constitutes an inspected portion 60 for confirming a coating position of a material forming an organic layer 40. Similarly, according to this configuration, effects similar to the effects in the above-described embodiment can be obtained.

### Fourth Modification Example of Embodiment

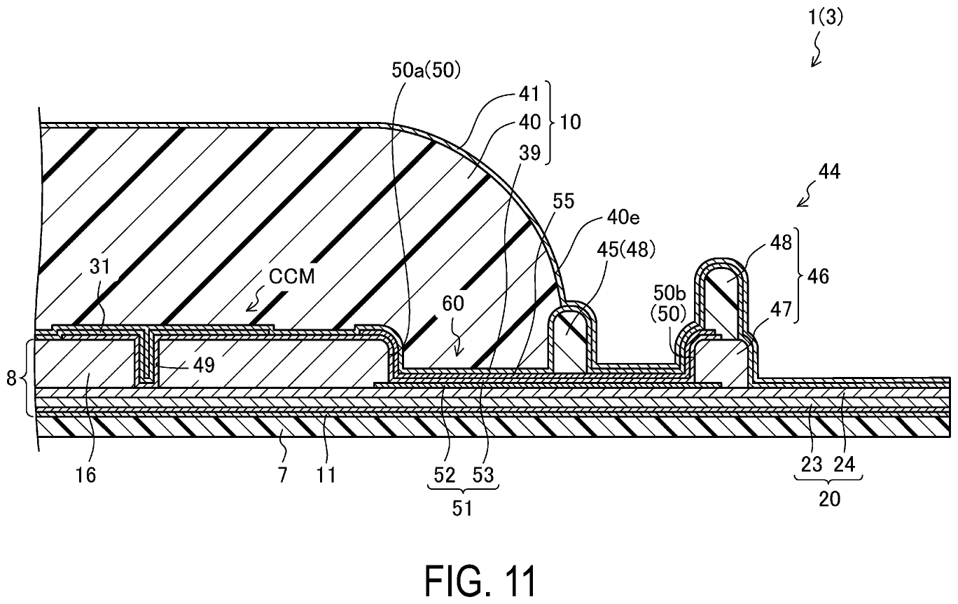

FIG. 11 is a view equivalent to FIG. 8 of an organic EL display device 1 according to a fourth modification example of the embodiment. In the organic EL display device 1 according to the embodiment described above, both the first dam wall 45 and the second dam wall 46 include a structure in which the first wall layer 47 and the second wall layer 48 are layered. However, as illustrated in FIG. 11, in the organic EL display device 1 according to the fourth modification example of the embodiment, a first dam wall 45 only includes a second wall layer 48. That is, the first dam wall 45 is formed of a material identical to a material of an edge cover 33 in a layer identical to a layer of the edge cover

As with the above-described embodiment, a second dam wall 46 includes a structure in which a first wall layer 47 and the second wall layer 48 are layered. The aspects of a light reflective portion 51 (a first metal layer 52 and a second metal layer 53) and a low reflection film 55 are similar to those in the embodiment described above. Then, a location at which the low reflection film 55 is provided constitutes an inspected portion 60 for confirming a coating position of a material forming an organic layer 40. Similarly, according to this configuration, the same effects as the effects in the above-described embodiment can be obtained.

### Fifth Modification Example of Embodiment

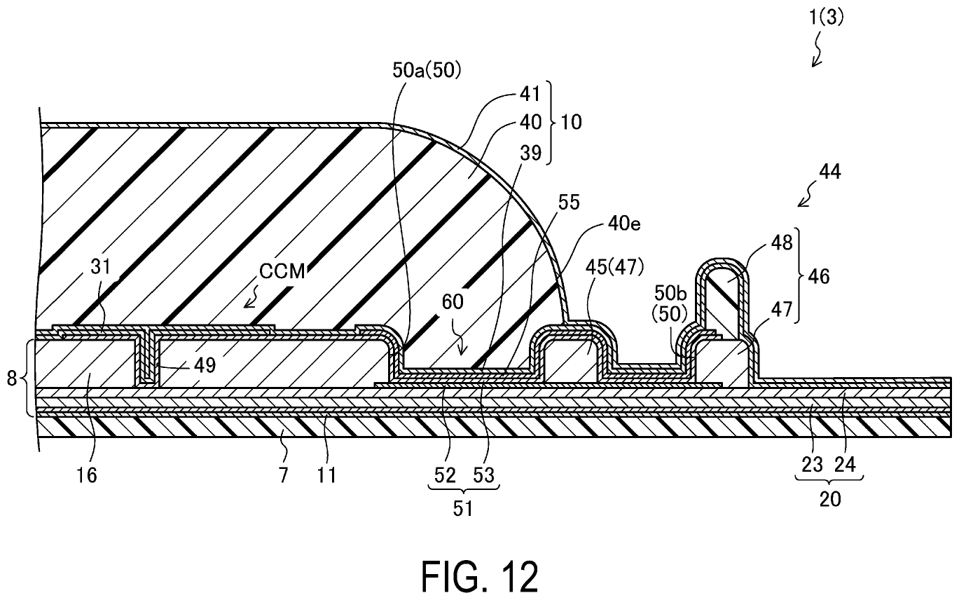

FIG. 12 is a view equivalent to FIG. 8 of an organic EL display device 1 according to a fifth modification example of the embodiment. In the organic EL display device 1 according to the embodiment described above, both the first dam wall 45 and the second dam wall 46 include a structure in which the first wall layer 47 and the second wall layer 48 are layered. However, as illustrated in FIG. 12, in the organic EL display device 1 according to the fifth modification example of the embodiment, a second dam wall 46 only includes a first wall layer 47. That is, a first dam wall 45 is formed of a material identical to a material of a flattening film 16 in a layer identical to a layer of the flattening film 16.

As with the above-described embodiment, the second dam wall 46 includes a structure in which the first wall layer 47 and a second wall layer 48 are layered. The aspects of a light reflective portion 51 (a first metal layer 52 and a second metal layer 53) and a low reflection film 55 are similar to those in the embodiment described above. Then, a location at which the low reflection film 55 is provided constitutes an inspected portion 60 for confirming a coating position of a material forming an organic layer 40. Similarly, according to this configuration, the same effects as the effects in the above-described embodiment can be obtained.

As described above, the preferred embodiment and the modification examples of the embodiment are described as examples of the technique of the present disclosure. However, the technique of the present disclosure is not limited to the embodiment and the modification examples, and is also applicable to an embodiment in which modification, replacement, adding, omission, and the like are suitably made. Additionally, the constituent elements described in the embodiment and the modification examples described above can be combined to make a new embodiment. Additionally, the constituent elements described in the attached drawings and the detailed description may include constituent elements that are not essential for solving the problem. Thus, even when the unessential constituent elements are described in the attached drawings and the detailed description, such unessential constituent elements are not to be directly regarded as essential constituent elements.

In the embodiment described above, the first metal layer 52 and the second metal layer 53 overlap each other inside the first slit 50a. However, the technique of the present disclosure is not limited to this embodiment. For example, the first metal layer 52 is provided only in a region in the frame region 3 in the outer side with respect to the first dam wall 45, and the second metal layer 53 is provided from the flattening film 16 to the second dam wall 46. The second metal layer 53 may overlap the first metal layer 52 only in the outer side of the first dam wall 45.

Additionally, in the embodiment described above, the example in which the material of the low reflection film 55 is molybdenum (Mo) is described. However, the technique of the present disclosure is not limited to this example. Molybdenum (Mo) is merely an example of the material of the low reflection film 55. As long as the material can make light reflectivity at the location at which the low reflection film 55 is provided lower than light reflectivity at the location at which the light reflective portion 51 (second metal layer 53) is exposed, the material may be a material including at least one element selected from molybdenum (Mo), titanium (Ti), tantalum (TO, tungsten (W), and chromium (Cr), and any material other than a metal material can be employed.

Additionally, in the embodiment described above, the organic layer 40 is provided from the display region 2 to the first dam wall 45. However, the technique of the present disclosure is not limited to this embodiment. For example, the organic layer 40 may be provided from the display region 2 to the second dam wall 46, or may be provided to the outer side of the second dam wall 46.

Additionally, in the embodiment described above, the light reflective portion 51 constitutes the low voltage power source wiring line 15lp electrically coupled to the second electrode 31. However, the technique of the present disclosure is not limited to this embodiment. The light reflective portion 51 may not constitute the low voltage power source wiring line 15lp, and may be a metal layer constituting other wiring lines or electrodes of other function portions.

Additionally, in the embodiment described above, the organic EL layer 30 is individually formed for each of the subpixels 6. However, the applicable range of the technique of the present disclosure is not limited to this embodiment. The organic EL layer 30 may be provided and shared by the plurality of subpixels 6. In this case, the organic EL display device 1 may include a color filter to perform color tone expression of each of the subpixels 6.

Additionally, in the present embodiment, the organic EL display device 1 using the resin substrate layer 7 as a substrate is described as an example, but the applicable range of the technique of the present disclosure is not limited to this embodiment. As the substrate, a substrate including an inorganic material such as glass and quartz, plastic such as polyethylene terephthalate, and ceramic such as alumina may be used. Additionally, the substrate may be a substrate being a metal substrate such as aluminum and iron including one surface coated with silica gel, an organic insulating material, or the like, or a substrate being a metal substrate including a surface subjected to insulation treatment by a method such as anode oxidation.

Additionally, in the embodiment described above, the first TFT 12 and the second TFT 13 employ a top gate type structure. However, the applicable range of the technique of the present disclosure is not limited to this embodiment. The first TFT 12 and the second TFT 13 may employ a bottom gate type structure.

Additionally, in the embodiment described above, the first TFT 12 and the second TFT 13 employ a top gate type structure. However, the applicable range of the technique of the present disclosure is not limited to this embodiment. The first TFT 12 and the second TFT 13 may employ a bottom gate type structure.

Additionally, in the embodiment described above, the organic EL display device 1 in which the first electrode 29 is an anode electrode and the second electrode 31 is a cathode electrode is described as an example. However, the applicable range of the technique of the present disclosure is not limited to this embodiment. The technique of the present disclosure is applicable to, for example, the organic EL display device 1 including the organic 1I, layer 30 including a reversed layered structure in which the first electrode 29 is a cathode electrode and the second electrode 31 is an anode electrode.

Additionally, in the embodiment described above, the organic EL display device 1 is described as an example of the display device, but the technique of the present disclosure is not limited to this embodiment. The technique of the present disclosure is applicable to a display device including a plurality of current-driven light-emitting elements, for example, a display device including a quantum dot light-emitting diode (QLED) that is a light-emitting element using a quantum dot-containing layer.

### INDUSTRIAL APPLICABILITY

As described above, the technique of the present disclosure is useful for a display device including a sealing structure in which a light-emitting element is covered with a sealing film including an organic layer.

### REFERENCE SIGNS LIST

CCM Control circuit region
1 Organic EL display device
2 Display region
3 Frame region
4 Terminal portion
5 Pixel
6, 6r, 6g, 6b Subpixel
7 Resin substrate layer (substrate)
8 TFT layer
9 Organic EL element (light-emitting element)
10 Sealing film
11 Base coat film
12 First TFT
13 Second ITT
14 Capacitor
15 Display wiring line
15g Gate wiring line
15s Source wiring line
15hp High voltage power source wiring line
15lp Low voltage power source wiring line
15f Frame wiring line
15t Wiring line terminal
16 Flattening film
17 Semiconductor layer
18 Gate insulating film
19 Gate electrode
20 Interlayer insulating film
21 Source electrode
22 Drain electrode
25, 28, 32 Contact hole
26 Lower conductive layer
27 Upper conductive layer
29 First electrode
30 Organic EL layer (function layer)
31 Second electrode
33 Edge cover
34 Hole injection layer
35 Hole transport layer
36 Light-emitting layer
37 Electron transport layer
38 Electron injection layer
39 First inorganic layer
40 Organic layer
40e Circumferential end edge of organic layer
41 Second inorganic layer
44 Dam structure
45 First dam wall
46 Second dam wall
47 First wall layer
48 Second wall layer
49 Trench
50 Slit
50a First slit
50b Second slit
51 Light reflective portion
52 First metal layer
53 Second metal layer
55 Low reflection film
60 Inspected portion

1. A display device comprising:
a substrate;
a first metal layer being provided on the substrate;
a flattening film being provided on the first metal layer;
a second metal layer and a plurality of light-emitting elements being provided on the flattening film; and
a sealing film covering the plurality of light-emitting elements,
wherein a display region and a frame region are provided, the display region in which an image is displayed by light emission of the plurality of light-emitting elements, and the frame region being positioned in a periphery of the display region,
the sealing film includes an organic layer, and the organic layer includes a circumferential end edge being positioned in the frame region,
a slit is formed in an outer side of the flattening film, the slit overlapping the circumferential end edge of the organic layer,
the first metal layer and the second metal layer are each provided across the slit, and are in contact with each other inside the slit,
a low reflection film is provided on the second metal layer at a location at which the organic layer and the slit overlap each other, the low reflection film having light reflectivity lower than light reflectivity of the second metal layer,
the plurality of light-emitting elements each include a first electrode, a function layer being provided on the first electrode, and a second electrode being provided on the function layer,
the second electrode is provided and shared by the plurality of light-emitting elements, and
the second metal layer is formed of a material identical to a material of the first electrode in a layer identical to a layer of the first electrode.

2. (canceled)

3. The display device according to claim 1,
wherein a trench is formed in the flattening film, the trench passing through the flattening film, and
the second metal layer and the second electrode cover an inner face of the trench, and are in contact with each other inside the trench.

4. The display device according to claim 3,
wherein the first metal layer is formed of a material identical to a material of a source wiring line in a layer identical to a layer of the source wiring line, the source wiring line being provided in the display region,
the second electrode is electrically coupled to the first metal layer via the second metal layer, and
the first metal layer and the second metal layer constitute a frame wiring line, the frame wiring line being provided in the frame region to surround the display region.

5. The display device according to claim 1,
wherein an edge cover is provided between the second metal layer and the second electrode in the display region,
a first dam wall surrounding the display region and a second dam wall surrounding the first dam wall are provided in the frame region,
the first dam wall is formed of a material identical to a material of the edge cover in a layer identical to a layer of the edge cover, and
the second dam wall includes a first wall layer and a second wall layer, the first wall layer being formed of a material identical to a material of the flattening film in a layer identical to a layer of the flattening film, and the second wall layer being formed of a material identical to a material of the edge cover in a layer identical to a layer of the edge cover.

6. The display device according to claim 1,
wherein an edge cover is provided between the second metal layer and the second electrode in the display region,
a first dam wall surrounding the display region and a second dam wall surrounding the first dam wall are provided in the frame region,
the first dam wall is formed of a material identical to a material of the flattening film in a layer identical to a layer of the flattening film, and
the second dam wall includes a first wall layer and a second wall layer, the first wall layer being formed of a material identical to a material of the flattening film in a layer identical to a layer of the flattening film, and the second wall layer being formed of a material identical to a material of the edge cover in a layer identical to a layer of the edge cover.

7. The display device according to claim 1,
wherein an edge cover is provided between the second metal layer and the second electrode in the display region,
a first dam wall surrounding the display region and a second dam wall surrounding the first dam wall are provided in the frame region, and
each of the first dam wall and the second dam wall includes a first wall layer and a second wall layer, the first wall layer being formed of a material identical to a material of the flattening film in a layer identical to a layer of the flattening film, and the second wall layer being formed of a material identical to a material of the edge cover in a layer identical to a layer of the edge cover.

8. The display device according to claim 5,
wherein the low reflection film is provided between the flattening film and the first dam wall.

9. The display device according to claim 5,
wherein the low reflection film is provided in a solid-like state between the flattening film and the first dam wall.

10. The display device according to claim 5,
wherein the low reflection film is provided in an island shape between the flattening film and the first dam wall.

11. The display device according to claim 10,
wherein a plurality of the low reflection films are provided at an interval along the first dam wall.

12. The display device according to claim 5,
wherein the low reflection film is provided from a side of the display region with respect to the first dam wall to a part between the first dam wall and the second dam wall.

13. The display device according to claim 1,
wherein the low reflection film is formed of a metal material.
